(19) United States
(12) Patent Application Publication
(10) Pub. No.: US 2017/0117433 A1
(43) Pub. Date: Apr. 27, 2017

(54) A HYBRID ALL-BACK-CONTACT SOLAR CELL AND METHOD OF FABRICATING THE SAME

(71) Applicant: Trina Solar Energy Development Pte Ltd, Singapore (SG)

(72) Inventors: Rolf Stangl, Singapore (SG); Thomas Mueller, Singapore (SG)

(21) Appl. No.: 15/300,562

(22) PCT Filed: Apr. 3, 2014
(86) PCT No.: PCT/SG2014/000149

§ 371 Date: Sep. 29, 2016

(51) Int. Cl. H01L 31/18; H01L 31/072; H01L 31/0463; H01L 31/0224; H01L 31/0216

(52) U.S. Cl. CPC H01L 31/1868; H01L 31/1876; H01L 31/022441; H01L 31/02167; H01L 31/0463; H01L 31/072

(57) ABSTRACT

A hybrid all-back-contact (ABC) solar cell and method of fabricating the same. The method comprises: forming one or more patterned insulating passivation layers over at least a portion of an absorber of the solar cell; forming one or more hetero junction layers over at least a portion of the one or more patterned insulating passivation layers to provide one or more heterojunction point or line-like contacts between the one or more heterojunction layers and the absorber of the solar cell; forming one or more first metal regions over at least a portion of the one or more heterojunction layers; forming a doped region within the absorber of the solar cell; and forming one or more second metal regions over at least a portion of the doped region and contacting the doped region to provide one or more homojunction contacts.

### FIELD OF INVENTION

The invention relates to a hybrid all-back-contact solar cell and method of fabricating the same.

### BACKGROUND

In typical industrial silicon wafer solar cells, p-type silicon wafers are used. Excess charge carrier separation is usually achieved by a full-area diffused p/n⁺ homojunction (minority carrier collection) and a full-area diffused p/p⁺ homojunction (majority carrier collection); and can be formed by a high temperature thermal diffusion process and a high temperature contact firing respectively (to create the emitter and the back surface field region (BSF) of the solar cell).

In order to improve the cell efficiency, n-type Si wafers can be used. Thus, light-induced degradation observed in p-type Cz silicon (due to metastable boron-oxygen complexes) can be avoided. Furthermore, higher open-circuit voltages can be reached as the electron capture coefficient is usually higher than the hole capture coefficient in crystalline silicon, thus n-type c-Si has a lower minority carrier recombination rate. Currently, there are two ways to improve the efficiency of a conventional front-contacted solar cell, either (1) the use of diffused homojunction point (or line) contacts; or (2) the use of thin film deposited full-area heterojunction contacts.

All-back-contact (ABC) solar cells (placing both contacts at the rear side of the solar cell and thus avoiding shading of the front side metal grid) have an even higher efficiency potential at the expense of added complexity of patterning the wafer rear surface and/or the thin film deposited layers. For ABC Si wafer solar cells, usually only one passivation layer is used on the back-side, i.e. only SiNₓ instead of AlOₓ and SiNₓ in order to avoid structuring efforts.

In high-efficiency silicon wafer solar cells, surface passivation is very important, and all sides of the wafer have to be efficiently passivated. If diffused homojunction point contacts are used (conventional homojunction approach), surface passivation is usually achieved by electrically insulating passivation layers which contain a large amount of interface charges (field effect passivation). Typically silicon nitride, SiNₓ, is used (large amount of positive interface charge), and more recently, aluminium oxide, AlOₓ (large amount of negative interface charge). Small openings are formed within these electrically insulating passivation layers in order to form highly doped homojunction point or line contacts. There are two types of diffused homojunction point contacts, i.e. either full-area diffusion which is only locally contacted by the metal point contacts, or local-area diffusion underneath the metal point contacts. The latter approach increases the open-circuit voltage potential of the solar cell, as there are less recombination active regions within the wafer, but at the expense of having to grow/deposit and pattern a diffusion mask.

If thin film deposited full-area heterojunction contacts are used (i.e. conventional heterojunction approach), surface passivation is usually achieved by electrically conducting thin film intrinsic buffer layers. This is typically thin film (<10 nm) intrinsic hydrogenated amorphous silicon, a-Si:H(i), which is further covered by thin film (<30 nm) p- or n-doped hydrogenated amorphous silicon, a-Si:H(p⁺), a-Si:H(n⁺), in order to form the emitter and the back-surface-field (BSF) region of the solar cell. Alternatively, instead of using a-Si:H(i), its sub-oxides, a-SiOₓ:H(i), can be used, leading to even better surface passivation. The intrinsic buffer layer may be omitted by directly depositing the doped thin film emitter or BSF layers, thereby accepting a slightly lower surface passivation in exchange of reducing the amount of layers. In order to form the full-area contacts, a thin film transparent conductive oxide (TCO) layer is applied on top of the thin film silicon layers. The TCO not only ensures lateral conductance but also serves as an effective back reflector. A metallic grid is formed on top of the TCO to extract the current.

However, the two approaches above have disadvantages. For example, conventional diffused homojunction silicon wafer solar cells suffer from a comparatively low open-circuit (V_{oc}) potential, because (1) the diffused regions within the wafer are also regions of high recombination, and (2) there is always a high contact recombination as the metallic contact is directly touching the solar cell absorber. Furthermore, there are issues with regard to boron p⁺ diffusion, such as a relatively low throughput, a very high thermal budget (>1000° C.), a large maintenance requirement for the tube (removal of boron powder), and it is a comparatively unstable process. While thin film deposited heterojunction silicon wafer solar cells have proven to attain the highest V_{oc} values, their cost effectiveness has yet to be proven. In particular, the TCO layers, which are required to provide a good lateral conductance as well as a good rear side reflectance, require an additional process (i.e. sputtering) and thus add significant cost.

Recently, a high-efficiency contacting scheme has been proposed, using thin film deposited heterojunction point-contacts within the context of ABC solar cells. However, this scheme has yet to be tested on a solar cell device. In an ABC heterojunction point contact solar cell, the diffused regions within the wafer are no longer needed to collect excess charge carriers of the solar cell absorber, as the huge amount of surface charge within the electrically insulating passivation layers can perform this function (i.e. it accumulates electrons or holes near the surface of the wafer). Thus, charge carrier separation is no longer performed by a (homo or hetero) p⁺/n or n⁺/n junction but by alternating surface charges of the two different electrically insulating passivation layers (i.e. AlOₓ and SiNₓ). The use of two different passivation layers which exhibit a large amount of positive or negative surface charge is essential. Excess charge carrier extraction can then be performed by a local opening of the passivation layer and a subsequent deposition of thin film heterojunction layers on top of the passivation layer, which have an effective doping which is of the opposite type as the polarity of the surface charges of the underlying passivation layers. In other words, the layers deposited on AlOₓ (negative surface charge) should be effectively p-doped (for example, a stack of an thin intrinsic amorphous silicon buffer layer and a p-doped amorphous silicon emitter layer, a-Si:H(i)/a-Si:H(p), or just a thin p-doped a-Si:H(p) emitter layer), and the layers deposited on SiNₓ (positive surface charge) are preferably effectively n-doped. In contrast to using full-area heterojunction contacts, it is not necessary to ensure perfect interface passivation as point contacts are used (the fraction of the point-contacted area to the total area is well below 20%, thus a higher interface recombination within these regions can be tolerated). Therefore, one can realize the heterojunction point-contact using microcrystalline silicon, μc-Si:H, instead of a-Si:H, thus accepting a bad passivation quality in exchange for a higher doping efficiency. Compared to a corresponding homojunction point contacting scheme (using the same geometrical dimensions of the point-contacts), even higher open-circuit voltages may be reached. This is due to (1) a lower contact recombination due to the band offsets of the hetero contact, specifically blocking one excess carrier of the solar cell absorber to reach the heterojunction material adjacent to the absorber and thus the metallic contact, and (2) there are no more highly diffused and thus recombination active regions within the solar cell absorber.

In summary, there are four different high-efficiency contacts known to extract excess electrons or holes from a solar cell absorber, i.e. (1) full-area diffused homojunction point/stripe-contacts, (2) locally diffused homojunction point/stripe-contacts, (3) thin film heterojunction deposited full-area contacts, and (4) thin film heterojunction deposited point/stripe-contacts. With the exception of (4), all other contacts have already been successfully implemented in solar cells, thus proving their ability to reach high efficiencies (>20%) for Si wafer solar cells. However, there is a significant amount of local structuring of the wafer and/or the passivation layers, which is necessary in order to realize these contacts, which is even increasing if all-back-contact solar cells are to be realized.

Disadvantages associated with each of the four types of contacts are elaborated below:

(1) Full-area diffused homojunction point/stripe-contacts need only one local opening process of the electrically insulating passivation layers (SiNx or AlOx). However, as the full-area diffused region within the wafer and the point/stripe-like metal-semiconductor interfaces are regions of high recombination, only comparatively low open-circuit voltages can be obtained.

(2) Locally diffused homojunction point/stripe-contacts require an additional local diffusion process within the wafer, which usually adds considerable complexity (and cost) to the solar cell process. However, compared to full-area diffused homojunction point/stripe-contacts they exhibit a higher V_{oc} potential, as less recombination active diffused areas remain within the wafer. However, the highly recombination active point/stripe-like metal-semiconductor absorber interfaces remain.

(3) Thin-film deposited heterojunction full-area contacts are able to achieve the highest open-circuit voltage up to now. This is due to (i) the inherent advantage of heterojunctions compared to homojunctions, being able to reduce contact recombination, and (ii) there are no more recombination active regions within the wafer. For the contact itself, no structuring is needed, as it is a full-area contact. However, if used in an all-back-contact solar cell, the amount of patterning significantly increases. For example, both the p+ and n+ a-Si:H regions, as well as the additional electrically insulating passivation layer (for example SiNₓ) in the gap between the two, needs to be defined with mutual alignment.

(4) Thin-film deposited heterojunction point/stripe contacts require only one structuring step (i.e. the local opening of the electrically insulating passivation layer) similar to full-area-diffused homojunction point/stripe contacts. In principle, they exhibit an even higher open-circuit potential than thin-film deposited heterojunction full-area contacts, as the highly recombination active thin-film heterojunction layers are decoupled from the solar cell absorber (everywhere with the exception of the point/stripe contact regions). For all-back-contact solar cells, neither the expensive TCO layer is needed (as SiNₓ or AlOₓ are able to form efficient back reflectors), nor an additional insulating layer separating the emitter layer from the BSF layer is needed. However, if such heterojunction point/stripe contacts are incorporated into all-back-contact solar cell structures, the amount of patterning needed is at least as complex as using full-area heterojunction contacts in all-back-contact solar cells.

A need therefore exists to provide an all-back-contact (ABC) solar cell architecture and a method of fabricating the same, that seeks to address at least one of the abovementioned problems.

### SUMMARY

According to the first aspect of the invention, there is provided a method of fabricating a hybrid all-back-contact (ABC) solar cell, the hybrid ABC solar cell comprising a homojunction contact system and a heterojunction contact system disposed on the rear side of the solar cell, the method comprising the steps of: forming one or more patterned insulating passivation layers over at least a portion of an absorber of the solar cell; forming one or more heterojunction layers over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers; forming one or more first metal regions over at least a portion of the one or more heterojunction layers; forming a doped region within the absorber of the solar cell, the doped region having a different doping level compared to the absorber of the solar cell; and forming one or more second metal regions over at least a portion of the doped region and contacting the doped region to provide one or more homojunction contacts, wherein the heterojunction contact system comprises the one or more first metal regions, the one or more heterojunction layers and the absorber of the solar cell; and the homojunction contact system comprises the one or more second metal regions, the doped region and the absorber of the solar cell.

In an embodiment, the method may further comprise the step of: doping the one or more heterojunction layers such that the polarity of the one or more heterojunction layers is opposite to the polarity of the one or more patterned insulating passivation layers.

In an embodiment, the method may further comprise the step of: creating surface charges at the interface of the one or more patterned insulating passivation layers and the absorber of the solar cell such that the polarity of the one or more patterned insulating passivation layers is opposite to the polarity of the one or more heterojunction layers.

In an embodiment, the method may further comprise the steps of: forming an emitter region on the rear side of the solar cell, the emitter region comprising the one or more homojunction contacts; and forming a back surface field region (BSF) region on the rear side of the solar cell, the BSF region comprising the one or more heterojunction point or line-like contacts, wherein the emitter region is disposed adjacent the BSF region.

In an embodiment, the method may further comprise the steps of: forming an emitter region on the rear side of the solar cell, the emitter region comprising the one or more heterojunction point or line-like contacts; and forming a back surface field region (BSF) region on the rear side of the solar cell, the BSF region comprising the one or more homojunction contacts, wherein the emitter region is disposed adjacent the BSF region.

In an embodiment, providing the one or more homojunction contacts may comprise forming one or more homojunction point or line-like contacts by diffusion, ion implantation or alloying.

In an embodiment, the one or more heterojunction layers may be formed by thin-film deposition.

In an embodiment, the method may further comprise the steps of: forming the doped region on the rear side of the absorber of the solar cell at least where the one or more second metal regions are to be disposed; and opening contact holes in the one or more patterned insulating passivation layers at least where the one or more heterojunction point or line-like contacts are to be disposed.

In an embodiment, forming the doped region on the rear side of the absorber of the solar cell may comprise performing a local alloying process from the one or more second metal regions into the absorber of the solar cell.

In an embodiment, the one or more second metal regions may be formed using a screen printing process.

In an embodiment, the method may further comprise the step of contact firing to create surface charges at the interface of the one or more patterned insulating passivation layers and the absorber of the solar cell.

In an embodiment, the step of forming the one or more patterned insulating passivation layers may comprise forming at least two insulating passivation layers, wherein the at least two insulating passivation layers may comprise oppositely-charged surface charges. In an embodiment, each of the at least two insulating passivation layers may comprise SiNx, AlOx or SiOx.

In an embodiment, the method may further comprise the step of structuring the absorber of the solar cell by laser ablation in order to separate the BSF region from the emitter region of the solar cell.

In an embodiment, laser ablation may be used to open the contact holes in the one or more insulating passivation layers.

In an embodiment, the one or more heterojunction layers may comprise p- or n-doped microcrystalline silicon. In another embodiment, the one or more heterojunction layers may comprise intrinsic, p- or n-doped amorphous silicon or its suboxides.

According to the second aspect of the invention, there is provided a hybrid all-back-contact (ABC) solar cell, comprising: one or more patterned insulating passivation layers formed over at least a portion of an absorber of the solar cell; one or more heterojunction layers formed over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers; one or more first metal regions formed over at least a portion of the one or more heterojunction layers; a doped region formed within the absorber of the solar cell, the doped region having a different doping level compared to the absorber of the solar cell; and one or more second metal regions formed over at least a portion of the doped region and contacting the doped region to provide one or more homojunction contacts; wherein the one or more first metal regions, the one or more heterojunction layers and the absorber of the solar cell define a heterojunction contact system; and the one or more second metal regions, the doped region and the absorber of the solar cell define a homojunction contact system; wherein the heterojunction contact system and homojunction contact system are disposed on the rear side of the solar cell.

In an embodiment, the hybrid ABC solar cell may further comprise: one or more doped heterojunction layers; and surface charges at the interface of the one or more patterned insulating passivation layers and the absorber of the solar cell, wherein the polarity of the one or more doped heterojunction layers is opposite to the polarity of the one or more patterned insulating passivation layers.

In an embodiment, the hybrid ABC solar cell may further comprise: an emitter region on the rear side of the solar cell, the emitter region comprising the one or more homojunction contacts; and a back surface field region (BSF) region on the rear side of the solar cell, the BSF region comprising the one or more heterojunction point or line-like contacts; wherein the emitter region is disposed adjacent the BSF region.

In an embodiment, the hybrid ABC solar cell may further comprise: an emitter region on the rear side of the solar cell, the emitter region comprising the one or more heterojunction point or line-like contacts; and a back surface field region (BSF) region on the rear side of the solar cell, the BSF region comprising the one or more homojunction contacts; wherein the emitter region is disposed adjacent the BSF region.

In an embodiment, the one or more homojunction contacts may be diffused, ion implanted or alloyed homojunction point or line-like contacts.

In an embodiment, the one or more heterojunction layers may be thin-film deposited heterojunction layers.

In an embodiment, the hybrid ABC solar cell may further comprise contact holes in the one or more patterned insulating passivation layers at least where the one or more heterojunction point or line-like contacts are disposed.

In an embodiment, the hybrid ABC solar cell may further comprise at least two insulating passivation layers, wherein the at least two insulating passivation layers may comprise oppositely-charged surface charges. In an embodiment, each of the at least two insulating passivation layers may comprise SiNx, AlOx or SiOx.

In an embodiment, the BSF region may be separated from the emitter region of the solar cell by laser ablation.

### BRIEF DESCRIPTION OF THE DRAWINGS

Example embodiments of the invention will be better understood and readily apparent to one of ordinary skill in the art from the following written description, by way of example only, and in conjunction with the drawings, in which:

FIG. 1 is a schematic of a hybrid all-back contact solar cell, comprising an n-type silicon wafer substrate, an emitter region formed by a heterojunction point contacting scheme and a back surface field region formed by local-area diffusion, using a masking step, according to an embodiment of the invention.

FIG. 2 is a schematic of a hybrid all-back contact solar cell, comprising an p-type silicon wafer substrate, an emitter region formed by a heterojunction point contacting scheme and a back surface field region formed by local Al interdiffusion, according to an embodiment of the invention.

FIG. 3 is a schematic of a hybrid all-back contact solar cell, comprising an n-type silicon wafer substrate, an emitter region formed by local Al interdiffusion and a back surface field region formed by a heterojunction point contacting scheme, according to an embodiment of the invention.

FIG. 4 is a schematic of a hybrid all-back contact solar cell, comprising a p-type silicon wafer substrate, an emitter region formed by full-area diffusion and a back surface field region formed by a heterojunction point contacting scheme, according to an embodiment of the invention.

FIG. 5 is a schematic of a hybrid all-back contact solar cell, comprising an n-type silicon wafer substrate, an emitter region formed by a heterojunction point contacting scheme and a back surface field region formed by local-area diffusion, using a masking step, according to another embodiment of the invention.

FIG. 6 is a schematic of a hybrid all-back contact solar cell, comprising an n-type silicon wafer substrate, an emitter region formed by local Al interdiffusion and a back surface field region formed by a heterojunction point contacting scheme, according to another embodiment of the invention.

FIG. 7 is a schematic of a hybrid all-back contact solar cell, comprising a p-type silicon wafer substrate, an emitter region formed by local-area diffusion, using a masking step, and a back surface field region formed by a heterojunction point contacting scheme, according to another embodiment of the invention.

FIG. 8 is a flow chart illustrating a method of fabricating a hybrid all-back-contact solar cell, according to an embodiment of the invention.

### DETAILED DESCRIPTION

Embodiments of the present invention provide “hybrid” all-back-contact (ABC) solar cell structures for silicon wafer based solar cells, using homojunction contacts for one (electron or hole extracting) rear-side contact system, and using heterojunction point or line/stripe (i.e. “line-like”) contacts for the other (hole or electron extracting) rear-side contact system for excess charge carrier extraction. The homojunction contacts may be diffused homojunction point or line/stripe contacts. The heterojunction point or line/stripe contacts may be formed by thin-film silicon deposition.

Embodiments of the present invention seek to significantly reduce structuring effort while only marginally compromising achievable open-circuit voltage by providing a “hybrid” ABC solar cell architecture. The “hybrid” ABC solar cell architecture combines a diffused homojunction point/stripe contact system (with the charge carrier accumulation region being located within the wafer) with a heterojunction point or line/stripe contact system (with the charge carrier accumulation region being located outside of the wafer), and seeks to ensure process compatibility between a homojunction and a heterojunction contact formation.

In a heterojunction point contacting scheme, charge carrier separation of electrons or holes within the solar cell absorber is directly established using an electrically insulating passivation layer for surface passivation, which exhibits either a large amount of positive or negative surface charge, thus driving the surface of the wafer into strong inversion or into strong accumulation. Thus, charge carrier accumulation near the contacts is performed by the surface charges of the electrically insulating passivation layers (i.e. AlOₓ, with its negative surface charge or SiNₓ with its positive surface charge). Charge carrier extraction is then realized by a local opening of the passivation layer followed by a full-area deposition of one (or several) electrical conducting thin-film heterojunction layers on top of the passivation layer, thereby forming heterojunction point or line contacts. The effective doping of these thin film heterojunction layers is opposite to the polarity of the surface charge of the passivation layer in order to be able to extract the collected excess charge carriers. In other words, the passivation layer adjacent to the heterojunction point or line-like contact exhibits a high fixed interface charge density towards the solar cell absorber, which is of the opposite polarity as the effective doping of the heterojunction layers applied on top of it. For example, the layers deposited on AlOₓ (negative surface charge) should be effectively p-doped (for example, a stack of an thin intrinsic amorphous silicon buffer layer and a p-doped amorphous silicon emitter layer, a-Si:H(i)/a-Si:H(p), or just a thin p-doped a-Si:H(p) emitter layer), and the layers deposited on SiNₓ (positive surface charge) are effectively n-doped. The heterojunction point-contact can be realized by using microcrystalline silicon, pc-Si:H, instead of a-Si:H, accepting a bad passivation quality in exchange for a higher doping efficiency. Contrary to conventional (homojunction) point contacting schemes, there is no diffused area underneath the contacts, which enables the solar cell to reach higher open-circuit voltages due to reduced contact and bulk recombination.

Embodiments of the present invention seek to provide advantages over both conventional diffused homojunction ABC solar cell structures and thin-film deposited heterojunction ABC solar cell structures; as well as seek to significantly reduce the structuring effort needed while only marginally compromising the achievable open-circuit voltage. Accordingly embodiments of the present invention provide “hybrid” (homojunction/heterojunction) all-back-contact (ABC) solar cell structures, using the heterojunction point or line/stripe contacting scheme described above for one rear contact system and using conventional diffused homojunction contacts for the other rear contact system, in a way that the corresponding homo/heterojunction contact formation processes are process compatible.

In an embodiment, the hybrid ABC solar cell comprises a homojunction contact system and a heterojunction contact system disposed on the rear side of the solar cell. The heterojunction contact system comprises one or more first metal regions, one or more heterojunction layers and an absorber of the solar cell. The homojunction contact system comprises one or more second metal regions, a doped region and the absorber of the solar cell.

It will be appreciated by a person skilled in the art that it is not feasible to simply combine the diffused homojunction approach and the thin-film deposited heterojunction approach within a solar cell, as the respective associated processes are not process compatible. In particular, thin-film heterojunction layers cannot withstand temperatures above 400° C., while screen printed diffused homojunction contacts require contact firing temperatures of 800° C. and above. Furthermore, if thin-film PECVD heterojunction deposition is performed, it is not advisable to have metal contacts within the deposition chamber, as this would result in a considerable cross contamination of the deposited heterojunction layers. Thus, the processes from the diffused homojunction approach and the thin-film deposited heterojunction approach cannot be simply combined in a straight-forward industrially compatible manner.

However, process compatibility can be advantageously achieved by the use of heterojunction point or line contacts according to example embodiments of the present invention as described herein. In particular, some degree of heterojunction layer degradation (either by high temperature treatment or by metal cross contamination) is intentionally accepted. The degradation affects a small area of the point or line contacts, thus a correspondingly lower passivation quality within these regions can be accepted. Metal cross contamination can be accepted especially if Aluminum is used and p-type heterojunction layers are deposited. The resulting hybrid ABC solar cell advantageously requires a significantly lower amount of structuring.

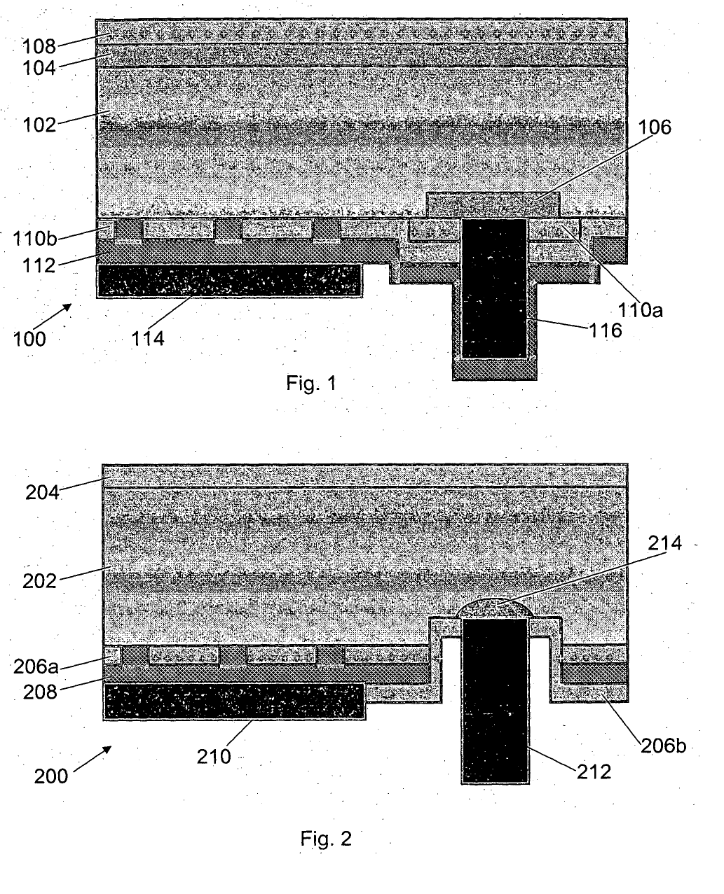

If a large pitch spacing (distance between equal contacts) is required (e.g. in order to use screen printing), the rear side emitter regions are preferably larger than the rear side back surface field (BSF) regions. This is because the generated minority carriers have to travel the whole distance to the next contact in order to be collected, whereas the generated majority carriers can as well remain in the substrate while other majority carriers within the wafer are collected in order to drive the current. In some cases, laser ablating can be advantageously used for structuring the wafer in order to form the rear side BSF regions, thereby significantly simplifying mutual alignment, compare FIGS. 2, 3, 4, 6, 7. In that case smaller BSF regions are preferably structured by laser ablation, as otherwise most parts of the wafer will have to be ablated, which is time consuming and thus not industrially feasible. In that case, the BSF regions are then advantageously formed either by the point/stripe-contacting heterojunction layers or by a local Al-interdiffusion via contact firing, in order to avoid a masking step for the contact formation.

According to an embodiment, there is provided a hybrid all-back-contact (ABC) solar cell, comprising: one or more patterned insulating passivation layers formed over at least a portion of an absorber of the solar cell; one or more heterojunction layers formed over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers; one or more first metal regions formed over at least a portion of the one or more heterojunction layers; a doped region formed within the absorber of the solar cell, the doped region having a different doping level compared to the absorber of the solar cell; and one or more second metal regions formed over at least a portion of the doped region and contacting the doped region to provide one or more homojunction contacts.

The one or more first metal regions, the one or more heterojunction layers and the absorber of the solar cell may define a heterojunction contact system. The one or more second metal regions, the doped region and the absorber of the solar cell may define a homojunction contact system. The heterojunction contact system and homojunction contact system may be disposed on the rear side of the solar cell.

The one or more heterojunction layers may be doped heterojunction layers. There may also be surface charges at the interface of the one or more patterned insulating passivation layers and the absorber of the solar cell.

According to an embodiment of the invention, there is provided an all-back-contact (ABC) solar cell, wherein the emitter formation is realised by a heterojunction point contacting scheme and the back surface field (BSF) formation is realised by conventional (local-area) diffusion, using a masking step. The emitter regions collect the excess charge minority carrier of the solar cell absorber. The BSF regions collect the excess charge majority carrier of the solar cell absorber.

If the emitter region of the hybrid ABC solar cell is formed by the heterojunction layer and an n-type silicon wafer is used, the gettering effect of phosphorus diffusion can be leveraged as shown on FIG. 1 (see below). However, the structuring effort is considerably higher compared to other all-back-contact embodiments of the invention described herein, as the BSF region is formed by phosphorus diffusion and thus a masking step is required to form the diffused contact (laser ablation is not used to structure the wafer in order avoid the masking step for the contact formation).

The process sequence may start with heavily doped phosphorus diffusion (full-area front side and locally back side) followed by a front-side etch back to obtain a moderately doped front surface field in order to enhance lateral current transport. The next step is front side passivation with SiNₓ and rear side passivation (using both, SiNₓ and AlOₓ). For the rear side passivation, further structuring is involved, such as full-area SiNₓ deposition, masking of the BSF area, selective etch back of SiNₓ covering the emitter area, and full-area deposition of AlOₓ, as laser ablation cannot be used. Alternatively, only one rear side passivation layer, which exhibits a large negative surface charge (like AlOₓ) but is still able to effectively passivate the diffusion-doped BSF region, can be used.

The next process sequence may involve (i) first finishing the diffused BSF contact by a high temperature contact firing and then completing the heterojunction point-contact (using low temperature metallisation and accepting Al metal cross contamination as the heterojunction point contacts are formed on p-doped thin film silicon layers); or alternatively, (ii) first depositing the thin film silicon layers for the heterojunction point contact formation (after a laser assisted opening of the contact holes), and then a high temperature contact firing step together with the front-contact formation (co-firing) may be applied, thereby accepting a decrease in passivation quality within the regions of the point contacts.

FIG. 1 is a schematic of a hybrid ABC solar cell, using an n-type silicon wafer, manufactured in accordance with the steps described above. The ABC solar cell 100 comprises an n-type silicon wafer 102, a phosphorus diffused etched back layer 104 on the front side, locally phosphorus diffused area 106 on the back side (obtained by masking), a front side SiNₓ passivation layer 108, and rear side SiNₓ 110a and AlO_{z} 110b passivation layers. The emitter contact region, which is formed by the heterojunction point contacting scheme, comprises an a-Si:H(p⁺) (or a pc-Si:H(p⁺)) layer 112, a locally opened AlOₓ passivation layer 110b (with its negative interface charge) and an aluminium metal contact 114. The back surface field (BSF) contact region, which is formed by conventional (masked, local-area) diffusion, comprises another metal contact 116 and the phosphorus diffused area 106.

If the emitter region of the hybrid ABC solar cell is formed by the heterojunction layer and a p-type silicon wafer is used, one can advantageously use laser ablating combined with a locally Al-diffused BSF formation achieved by contact firing, as shown on FIG. 2. In this instance, no additional structuring steps are necessary as the laser ablation is able to separate the two regions at the back side of the wafer, so that full-area depositions of the thin film passivation layers as well as the thin film heterojunction layers can be applied. In other words, there is neither a separate diffusion step nor additional structuring effort. However, one has to now apply a high temperature contact formation after the thin film silicon heterojunction layer depositions. This means one has to accept that the metal contact formation takes place on n-type doped heterojunction layers. Therefore, highly doped n-type microcrystalline silicon, pc-Si:H(n⁺) is preferably used for the heterojunction point-contact formation.

The process sequence may start with front and back side passivation (by using any kind of passivation layer for the front side and using SiNₓ passivation for the rear-side), followed by laser assisted local opening of the contact holes and a subsequent deposition of the thin film silicon heterojunction layers, i.e. μc-Si:H(n⁺). Laser ablation then creates a groove for the BSF region. Next, full-area passivation (using AlOₓ or any other passivation layer) is followed by high temperature contact firing (co-firing of the heterojunction contact and BSF contact, to form the locally Al-diffused BSF region) to complete the cell.

FIG. 2 is a schematic of a hybrid ABC solar cell, using an p-type silicon wafer, manufactured in accordance with the steps described above. The ABC solar cell 200 comprises a p-type silicon wafer 202, a front side passivation layer 204, and rear side passivation layers 206a (i.e. SiNₓ) and 206b. The emitter region, which is formed by the heterojunction point contacting scheme, comprises a μc-Si:H(n⁺) layer 208, a locally opened SiNₓ layer 206a (with its positive interface charge) and a metal contact 210. The back surface field (BSF), which is formed by conventional (local-area Al) interdiffusion, comprises an aluminium contact 212, an Al diffused area 214 and the passivation layer 206b.

An advantage of the two hybrid ABC solar cell structures according to embodiments of the present invention described above is that the large emitter area is used for heterojunction contact formation, and the small BSF area is used for homojunction contact formation. Therefore the higher open-circuit potential of heterojunctions can be better harvested. However, a disadvantage of these structures is that the contact fingers of the metal grid are of unequal width, so that either a thickening of the thinner metal fingers covering the BSF regions or more busbars may be required in order to reduce the series resistance of the rear-side interdigitated metal grid.

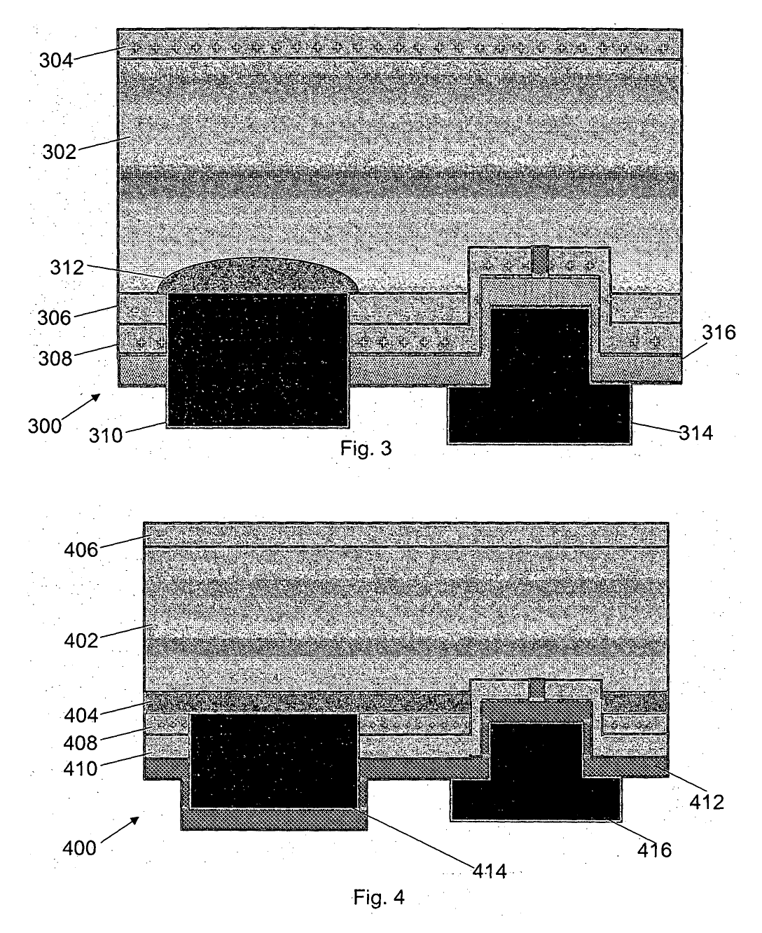

According to another embodiment of the invention, there is provided an all-back-contact (ABC) solar cell, wherein the emitter formation is realised by conventional (full-area or local-area) diffusion and the back surface field (BSF) formation is realised by a heterojunction point/stripe contacting scheme. The emitter region collects the excess charge minority carrier of the solar cell absorber. The BSF region collects the excess charge majority carrier of the solar cell absorber. In this embodiment, equal metal finger width can be advantageously achieved, as shown in FIGS. 3 and 4.

If an n-type wafer is used, there is neither a separate diffusion step nor additional structuring effort in order to realize the solar cell structure. Furthermore, one can choose to either apply a low temperature second metallisation for the BSF contact formation (having to accept metal cross contamination within the regions of the point contacts); or choose a high temperature co-firing process (having to accept that the metal contact formation takes place on n-type doped heterojunction layers) preferably using μc-Si:H(n⁺), as shown in FIG. 3 (see below).

The process sequence may start with front and back side passivation (using any passivation layer, for example advantageously SiNₓ for the front-side and AlOₓ for the rear-side), followed by laser ablation in order to form the groove for the BSF region, and a subsequent deposition of a rear side SiNₓ passivation layer (with its positive interface charge).

The next process sequence may involve (i) first finishing the diffused emitter contact by a high temperature contact firing and then completing the heterojunction point-contact within the laser formed groove (by forming laser assisted openings within the SiNₓ and a subsequent full area deposition of the thin film heterojunction layers followed by a low temperature contact formation); or alternatively, (ii) first depositing the thin film silicon layers for the heterojunction point contact formation (after a laser assisted opening of the contact holes), and then applying a high temperature contact firing step together with the emitter contact formation (co-firing).

FIG. 3 is a schematic of a hybrid ABC solar cell, using an n-type silicon wafer, manufactured in accordance with the steps described above. The ABC solar cell 300 comprises an n-type silicon wafer 302, a front side passivation layer 304, and rear side passivation layers 306 and 308 (i.e. SiNₓ). The emitter region, which is formed by conventional (local-area Al) interdiffusion, comprises an aluminium contact 310 and an Al diffused area 312. The back surface field (BSF), which is formed by the heterojunction point/stripe contacting scheme, comprises another metal contact 314, a locally-opened SiNₓ passivation layer 308 (with its positive interface charge) and a μc-Si:H(n⁺) layer 316.

If a p-type wafer is used, there is no significant structuring effort necessary in order to realize the solar cell structure. The gettering effect of phosphorus diffusion can be advantageously used. Again, there is the choice of applying high temperature co-firing or a second low temperature metallisation. However, in this instance, neither the high temperature co-firing process nor the metal cross contamination induced by a second low temperature metallisation can cause issues, thus appropriate thin film silicon layers may be used.

The process sequence may start with moderately doped phosphorus diffusion to form the rear side emitter (and eventually also simultaneously a front side floating emitter for increased lateral transport), followed by corresponding front and back side passivation (using any passivation layers, preferably AlOₓ for the front-side and SiNₓ for the rear-side). Thereafter, laser ablation is performed in order to form the groove for the BSF region, and a subsequent deposition of the rear side AlOₓ passivation layer (with its negative interface charge).

The next process sequence may involve (i) first finishing the diffused emitter contact by a high temperature contact firing and then completing the heterojunction point-contact within the laser formed groove (by forming laser assisted openings within the SiNx and a subsequent full area deposition of the thin film heterojunction layers followed by a low temperature contact formation, thereby advantageously accepting metal cross contamination within the regions of the heterojunction point contacts); or alternatively, (ii) first depositing the thin film silicon layers for the heterojunction point contact formation (after a laser assisted opening of the contact holes), and then applying a high temperature contact firing step together with the emitter contact formation (co-firing), thereby advantageously accepting the degradation of the passivation quality within the regions of the point contacts due to the high temperature treatment.

FIG. 4 is a schematic of a hybrid ABC solar cell, using a p-type silicon wafer, manufactured in accordance with the steps described above. The ABC solar cell 400 comprises a p-type silicon wafer 402, a rear-side full-area phosphorus diffused region 404, a front side passivation layer 406, and rear side passivation layers 408 and 410 (i.e. AlOₓ). The emitter region, which is formed by conventional full-area diffusion, comprises a metal contact 414 and the phosphorus diffused region 404. The back surface field (BSF), which is formed by the heterojunction point contacting scheme, comprises an aluminium contact 416, a locally-opened AlOₓ passivation layer 410 (with its negative interface charge) and a μc-Si:H(p⁺) layer 412.

Embodiments of the present invention seek to provide advantages over both a conventional diffused homojunction ABC solar cell structure as well as a full-area deposited heterojunction ABC solar cell structure (i.e. not using a heterojunction point contacting scheme), such as:
(1) the amount of structuring (and thus the number of process steps) needed in order to realize an ABC solar cell structure is significantly reduced. This is possible by using the hybrid ABC solar cell structure according to embodiments of the invention, thereby realizing one rear-side contact “inside” the wafer (i.e. by conventional diffusion) and the other rear-side contact “outside” the wafer (i.e. by thin-film heterojunction layer deposition).
(2) the use of the point-heterojunction contacting scheme (compared to a full-area heterojunction contacting scheme) advantageously provides process compatibility between the high temperature requirements of diffused contacts (diffusion, contact firing) and the low temperature requirements usually needed for full-area contacting heterojunction solar cells. In other words, when using a point contacting scheme instead of a full-area contacting scheme, a loss in the passivation quality of the heterojunction layer can be tolerated as only a small fraction of the heterojunction layer is in direct contact to the solar cell absorber. This loss in passivation quality can either stem from a short high temperature treatment (needed for contact firing of the diffused homojunction contact system, if the metallisation for both contacts are performed within one single process step) or it can stem from a metal cross contamination within the PECVD chamber (if the metal contact for the first diffused contact system is processed before the thin-film deposition of the heterojunction layers of the second contact system).
(3) the use of the point heterojunction contacting scheme avoids the use of (comparatively expensive) transparent conductive oxide layers (TCO).

Furthermore, the embodiments are constructed in such a way that in ABC solar cells where
(4a) full-area diffusion for the diffused contact system is used: phosphorous diffusion (which is a robust and well established process in solar cell industry) is advantageously used for the diffused homojunction contact formation, thereby keeping the advantage of “gettering” (improvement of the wafer quality due to the phosphorous diffusion process step), while omitting the problematic boron diffusion (which is a comparatively unstable process step with a very narrow process window); or
(4b) local-area diffusion for the diffused contact system is used: local-area Al interdiffusion is advantageously realized by aluminium inter-diffusion from the Al contact fingers (self-aligned process, realized by simple high temperature contact firing), so that masking processes can be avoided and even a conventional tube or inline diffusion process can be omitted.

Hybrid (diffused homojunction and point/stripe-contacted heterojunction) ABC solar cell structures, according to embodiments of the present invention, are constructed in such a way, that it:
(a) Significantly decreases the amount of structuring but maintaining a high open-circuit voltage potential for the solar cell. Four design criteria apply: (I) one selective contact (withdrawing electrons or holes respectively) is realized “within” the wafer (diffused contact), while the other selective contact is realized “outside” of the wafer (thin film deposited heterojunction point contact); (II) the use of a self-aligned contact firing step in order to achieve a locally highly p-doped Al diffused region underneath the contact fingers can be considered, if the diffused contact is the hole extracting contact; (III) the use of laser assisted wafer structuring may be used in order to minimize mutual alignments by forming grooves for the back-surface field areas of the solar cell; and (IV) the use of a heterojunction point-contacting scheme allows substantially complete insulation of the electron collecting regions from the hole collecting regions, so that local internal shunting can be avoided.
(b) Uses phosphorous diffusion (which is a robust and well established process in the solar cell industry). If full-area diffusion is used for the diffused contact system, the advantage of “gettering” is kept (improvement of the wafer quality due to the phosphorous diffusion process step), while omitting boron diffusion (which is a comparatively unstable process step with a very narrow process window).
(c) Provides process compatibility between the high temperature requirements needed for conventional diffusion and contact firing, and the low temperature requirements usually needed for heterojunction contact formation. This is basically a consequence of using a heterojunction point-contacting scheme and avoiding a second high temperature diffusion process step. As local heterojunction point or line contacts are used to form the thin-film deposited heterojunction contact, this contact system is advantageously able to withstand a short high temperature load (i.e. contact firing). This is not the case if full-area heterojunction contacts are used instead. It will be understood by a person skilled in the art that the passivation quality of a-Si:H (or a-SiOₓ:H) degrades if temperatures higher than 450° C. are applied. This is due to the release of hydrogen, thereby creating recombination active dangling bond defects within the thin film silicon layer. As a direct consequence, either all high temperature processes have to be applied first (i.e. diffusion and contact firing), or a heterojunction contact formation process, which can tolerate a short high temperature process (i.e. contact firing), has to be developed. This is the case if thin film deposited heterojunction point contacts are used. A short high temperature treatment of the already formed contact system (i.e. a contact firing step needed for the diffused homojunction contact formation) can now be tolerated. There is a degradation of the passivation quality within the regions of the heterojunction point contacts during a high temperature treatment; however as the fraction of the point contact area to the total area is well below 20%, a high recombination within these regions can be tolerated. Furthermore, recombination within these regions is still lower compared to a homojunction point contact scheme due to the reasons described above. As such, the heterojunction point contact can be realized using μc-Si:H instead of a-Si:H, thus accepting a bad passivation quality but enabling a higher doping efficiency.
(d) Provides process compatibility between the metallisation step and the thin film heterojunction layer deposition step, avoiding or accepting metal cross contamination. It will be understood by a person skilled in the art that plasma enhanced chemical vapour deposition (PECVD) of thin film layers on substrates which exhibit some metallic areas on its surface to be deposited leads to metal cross contamination. In other words, the corresponding metal atoms are incorporated within the thin-film layer, possibly degrading the desired thin film layer properties. Using thin film deposited heterojunction point contacts, most of the area of the heterojunction layer is electrically decoupled from the solar cell absorber (only within the point contact regions there is a coupling). Thus Aluminium (Al) metal cross contamination can be accepted, especially if p-doped heterojunction layers are to be deposited, as Al primarily acts as a (recombination active) p-type dopant in such layers. In that case, Al contact firing step of the diffused homojunction formation can be performed before thin-film heterojunction layer deposition, thereby accepting an Al metal cross contamination but achieving a significant reduction of structuring (the thin film layer simply covers the metallic contact finger).

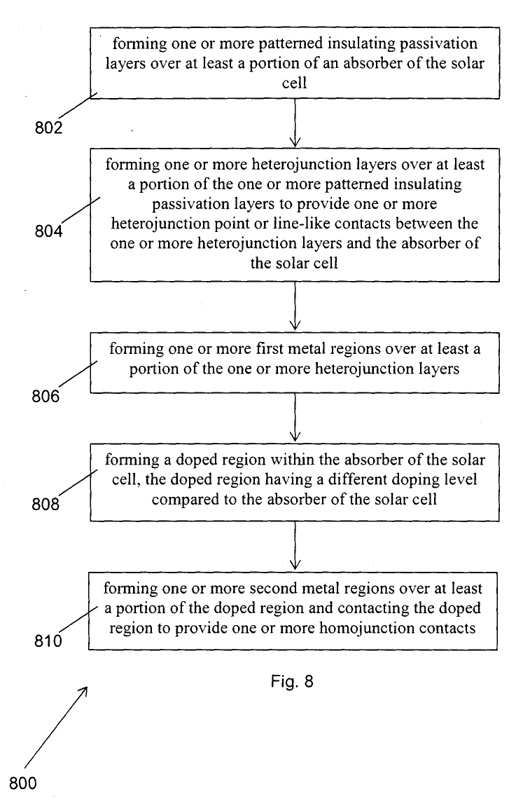

FIG. 8 is a flow chart 800 illustrating a method of fabricating a hybrid all-back-contact (ABC) solar cell, according to an embodiment of the invention. The hybrid ABC solar cell comprises a homojunction contact system and a heterojunction contact system disposed on the rear side of the solar cell. At step 802, one or more patterned insulating passivation layers are formed over at least a portion of an absorber of the solar cell. At step 804, one or more heterojunction layers are formed over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers. At step 806, one or more first metal regions are formed over at least a portion of the one or more heterojunction layers. At step 808, a doped region is formed within the absorber of the solar cell, the doped region having a different doping level compared to the absorber of the solar cell. At step 810, one or more second metal regions are formed over at least a portion of the doped region and contacting the doped region to provide one or more homojunction contacts. The heterojunction contact system comprises the one or more first metal regions, the one or more heterojunction layers and the absorber of the solar cell. The homojunction contact system comprises the one or more second metal regions, the doped region and the absorber of the solar cell.

The method may further comprise the steps of: (i) doping the one or more heterojunction layers; and (ii) creating surface charges at the interface of the one or more patterned insulating passivation layers and the absorber of the solar cell, such that the polarity of the one or more heterojunction layers is opposite to the polarity of the one or more patterned insulating passivation layers. The surface charges at the interface may be created by contact firing. In another embodiment, there may be distributed charges within the insulating passivation layers.

In an embodiment, the one or more homojunction contacts may be point or line-like contacts formed by diffusion, ion implantation or alloying. In an embodiment, the one or more heterojunction layers may be formed by thin-film deposition.

In an embodiment, the doped region may be formed on the rear side of the absorber of the solar cell at least where the one or more second metal regions are to be disposed. The doped region may be formed by performing a local alloying process from the one or more second metal regions into the absorber of the solar cell. The one or more second metal regions may be formed using a screen printing process.

In an embodiment, contact holes may be opened in the one or more patterned insulating passivation layers at least where the one or more heterojunction point or line-like contacts are to be disposed.

In an embodiment, there may be at least two insulating passivation layers, wherein the at least two insulating passivation layers comprise oppositely-charged surface charges. Each of the at least two insulating passivation layers may comprise SiNₓ, AlOₓ or SiOₓ.

In an embodiment, the one or more heterojunction layers may comprise p- or n-doped microcrystalline silicon. In another embodiment, the one or more heterojunction layers may comprise intrinsic, p- or n-doped amorphous silicon or its suboxides.

It will be appreciated by a person skilled in the art that numerous variations and/or modifications may be made to the present invention as shown in the embodiments without departing from a spirit or scope of the invention as broadly described. The embodiments are, therefore, to be considered in all respects to be illustrative and not restrictive.

For example, while only embodiments using n-type or p-type wafers respectively are outlined above, corresponding configurations using the opposite doped wafer can be derived accordingly. For all embodiments described above, instead of single AlOₓ layers, a stack of AlOₓ/SiNₓ may be used in order to provide process stability for chemical wafer cleaning processes or contact firing processes.

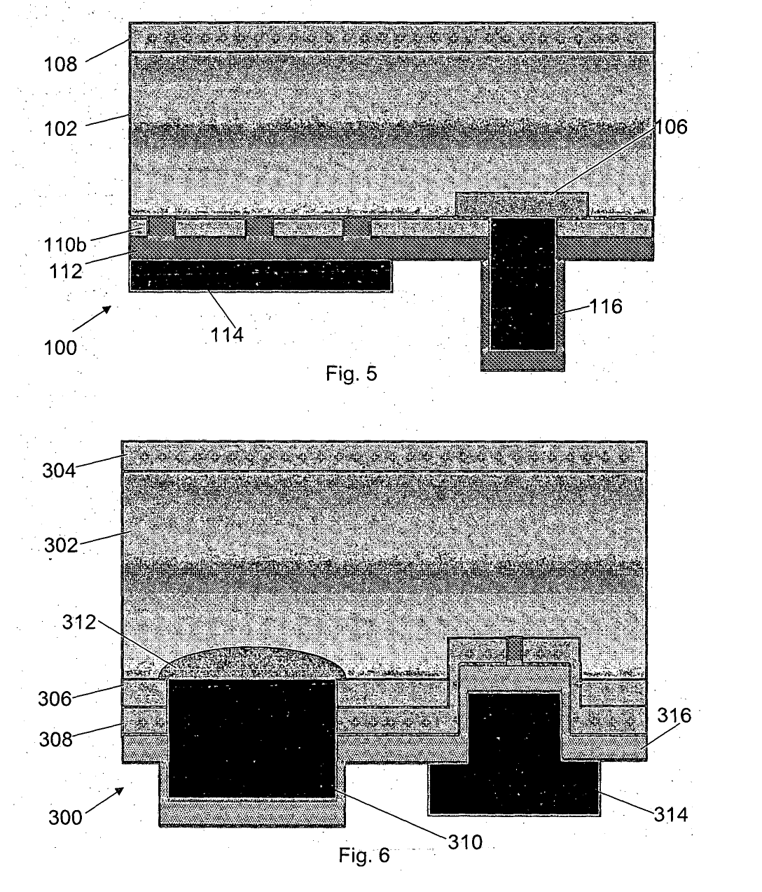

Front-side passivation for all-back-contact solar cells typically involves using a front-surface field (as shown in FIG. 1). However, a floating emitter may be used instead, or a diffused front side region may not be used at all (see FIG. 5). Consequently, various types of layers used for front side passivation may be applied, for example SiNₓ or AlOₓ (as discussed herein), and also silicon oxide, SiOₓ, or SiOₓ/SiNₓ, SiOₓ/AlOₓ, SiOₓ/AlOₓ/SiNₓ stacks, or thin film intrinsic amorphous silicon, a-Si:H(i). Also, instead of using two different rear-side passivation layers, exhibiting opposite surface charges, only one passivation layer 110b may be used (see FIG. 5), in order to reduce the number of process steps.

Furthermore, high temperature contact firing can be applied either before or after the deposition of the thin film silicon layers in order to form the heterojunction point contact. Slightly different cell structures are obtained depending whether high temperature contact firing is applied before or after the deposition of the thin film silicon layers, i.e. the thin-film silicon layers either cover or do not cover the metal grid formed by the diffused contact respectively. For example, FIG. 6 shows a hybrid diffused-emitter/heterojunction-point-contacted-BSF all-back-contact solar cell according to an embodiment of the present invention, wherein the diffused junction contact firing is applied first (as opposed to FIGS. 3 and 4, wherein a single co-firing step has been applied in order to form both metal contacts). In this case, highly passivation thin film silicon layers are advantageously used instead of using μc-Si:H.

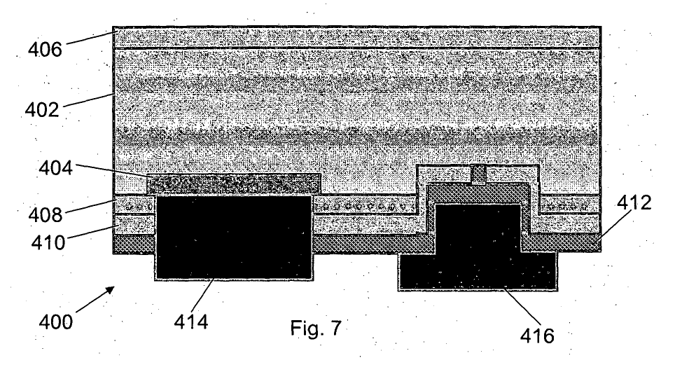

Furthermore, the diffused contact can be realized as a (low temperature) locally diffused contact, i.e. by applying laser chemical processing and subsequent plating. A low temperature contact advantageously allows the thin film layer deposition to be perform before the diffused contact formation, thereby avoiding metal cross contamination and being able to use thin-film silicon layers with highest passivation ability as no high temperature steps for diffused contact formation are needed, compare FIG. 7 to FIG. 4.

1. A method of fabricating a hybrid all-back-contact (ABC) solar cell, which solar cell has a front side and a rear side, the hybrid ABC solar cell comprising a homojunction contact system and a heterojunction contact system disposed on the rear side of the solar cell, the method comprising the steps of:
forming one or more patterned insulating passivation layers over at least a portion of an absorber of the solar cell, which absorber has a front side and a rear side;
forming one or more heterojunction layers over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers;
forming one or more first metal regions over at least a portion of the one or more heterojunction layers;
forming a doped region within the absorber of the solar cell, the doped region having a different doping level compared to the absorber of the solar cell; and
forming one or more second metal regions over at least a portion of the doped region and contacting the doped region to provide one or more homojunction contacts,
wherein the heterojunction contact system comprises the one or more first metal regions, the one or more heterojunction layers and the absorber of the solar cell; and the homojunction contact system comprises the one or more second metal regions, the doped region and the absorber of the solar cell.

2. The method as claimed in claim 1, further comprising the step of: doping the one or more heterojunction layers such that the polarity of the one or more heterojunction layers is opposite to the polarity of the one or more patterned insulating passivation layers.

3. The method as claimed in claim 1, further comprising the step of:
creating surface charges at the interface of the one or more patterned insulating passivation layers and the absorber of the solar cell such that the polarity of the one or more patterned insulating passivation layers is opposite to the polarity of the one or more heterojunction layers.

4. The method as claimed in claim 1, further comprising the steps of:
forming an emitter region on the rear side of the solar cell, the emitter region comprising the one or more homojunction contacts; and
forming a back surface field region (BSF) region on the rear side of the solar cell, the BSF region comprising the one or more heterojunction point or line-like contacts,
wherein the emitter region is disposed adjacent the BSF region.

5. The method as claimed in claim 1, further comprising the steps of:
forming an emitter region on the rear side of the solar cell, the emitter region comprising the one or more heterojunction point or line-like contacts; and
forming a back surface field region (BSF) region on the rear side of the solar cell, the BSF region comprising the one or more homojunction contacts,
wherein the emitter region is disposed adjacent the BSF region.

6. The method as claimed in claim 1, wherein providing the one or more homojunction contacts comprises forming one or more homojunction point or line-like contacts by diffusion, ion implantation or alloying.

7. The method as claimed in claim 1, wherein the one or more heterojunction layers are formed by thin-film deposition.

8. The method as claimed in claim 1, further comprising the steps of:
forming the doped region on the rear side of the absorber of the solar cell at least where the one or more second metal regions are to be disposed; and
opening contact holes in the one or more patterned insulating passivation layers at least where the one or more heterojunction point or line-like contacts are to be disposed.

9-11. (canceled)

12. The method as claimed in claim 1, wherein the step of forming the one or more patterned insulating passivation layers comprises forming at least two insulating passivation layers, wherein the at least two insulating passivation layers comprise oppositely-charged surface charges.

13. (canceled)

14. The method as claimed in claim 4, further comprising the step of structuring the absorber of the solar cell by laser ablation in order to separate the BSF region from the emitter region of the solar cell.

15. The method as claimed in claim 5, further comprising the step of structuring the absorber of the solar cell by laser ablation in order to separate the BSF region from the emitter region of the solar cell.

16-17. (canceled)

18. A hybrid all-back-contact (ABC) solar cell, which solar cell has a front side and a rear side, comprising:
one or more patterned insulating passivation layers formed over at least a portion of an absorber of the solar cell, which absorber has a front side and a rear side;
one or more heterojunction layers formed over at least a portion of the one or more patterned insulating passivation layers to provide one or more heterojunction point or line-like contacts between the one or more heterojunction layers and the absorber of the solar cell, wherein the polarity of the one or more patterned insulating passivation layers is opposite to the polarity of the one or more heterojunction layers;
one or more first metal regions formed over at least a portion of the one or more heterojunction layers;
a doped region formed within the absorber of the solar cell, the doped region having a different doping level compared to the absorber of the solar cell; and
one or more second metal regions formed over at least a portion of the doped region and contacting the doped region to provide one or more homojunction contacts; wherein the one or more first metal regions, the one or more heterojunction layers and the absorber of the solar cell define a heterojunction contact system; and the one or more second metal regions, the doped region and the absorber of the solar cell define a homojunction contact system; wherein the heterojunction contact system and homojunction contact system are disposed on the rear side of the solar cell.

19. The hybrid ABC solar cell as claimed in claim 18, further comprising:
one or more doped heterojunction layers; and
surface charges at the interface of the one or more patterned insulating passivation layers and the absorber of the solar cell, wherein the polarity of the one or more doped heterojunction layers is opposite to the polarity of the one or more patterned insulating passivation layers.

20. The hybrid ABC solar cell as claimed in claim 18, further comprising:
an emitter region on the rear side of the solar cell, the emitter region comprising the one or more homojunction contacts; and
a back surface field region (BSF) region on the rear side of the solar cell, the BSF region comprising the one or more heterojunction point or line-like contacts;
wherein the emitter region is disposed adjacent the BSF region.

21. The hybrid ABC solar cell as claimed in claim 18 or 19, further comprising:
an emitter region on the rear side of the solar cell, the emitter region comprising the one or more heterojunction point or line-like contacts; and
a back surface field region (BSF) region on the rear side of the solar cell, the BSF region comprising the one or more homojunction contacts;
wherein the emitter region is disposed adjacent the BSF region.

22. The hybrid ABC solar cell as claimed in claim 18, wherein the one or more homojunction contacts are diffused, ion implanted or alloyed homojunction point or line-like contacts.

23. The hybrid ABC solar cell as claimed in claim 18, wherein the one or more heterojunction layers are thin-film deposited heterojunction layers.

24. The hybrid ABC solar cell as claimed in claim 18, further comprising contact holes in the one or more patterned insulating passivation layers at least where the one or more heterojunction point or line-like contacts are disposed.

25. The hybrid ABC solar cell as claimed in claim 18, comprising at least two insulating passivation layers, wherein the at least two insulating passivation layers comprise oppositely-charged surface charges.

26. (canceled)

27. The hybrid ABC solar cell as claimed in claim 20, wherein the BSF region is separated from the emitter region of the solar cell by laser ablation.

28-29. (canceled)

30. The hybrid ABC solar cell as claimed in claim 21, wherein the BSF region is separated from the emitter region of the solar cell by laser ablation.
